(19) United States
(12) Patent Application Publication
(10) Pub. No.: US 2011/0156550 A1
(43) Pub. Date: Jun. 30, 2011

(54) ELECTRONIC DEVICE HAVING IMPROVED LEG

(76) Inventor: Shinji Hiratomo, Tokyo (JP)

(21) Appl. No.: 12/898,328

(22) Filed: Oct. 5, 2010

(30) Foreign Application Priority Data
Dec. 28, 2009 (JP) 2009-298503

(51) Int. Cl. H05K 5/02

(52) U.S. Cl. 312/223.1

(57) ABSTRACT

An electronic device includes: a case comprising a bottom wall; a leg portion that protrudes downward from the bottom wall and supports the case when the case is placed; and a functional component disposed above the leg portion, wherein the lowest point of the functional component is located at the same position as the height of the bottom wall or in the leg portion.

### CROSS-REFERENCE TO THE RELATED APPLICATION(S)

The present application is based upon and claims priority from prior Japanese Patent Application No. 2009-298503, filed on Dec. 28, 2009, the entire contents of which are incorporated herein by reference.

### FIELD

Embodiments described herein generally relate to an electronic device, such as a notebook-type personal computer, being designed to decrease thickness while employing multiple functions.

### BACKGROUND

In recent years, in an electronic device such as a notebook-type personal computer, many functional components such as a connector used for the connection to an external device and a TV jack used for receiving video/audio data for a television or the like have been provided in a side wall of a case in order to realize multiple functions.

Particularly, in this kind of the connector or TV jack, since a standard size is determined in advance, the maker cannot arbitrarily change the size. For this reason, the size of the connector or jack is comparatively large. Accordingly, it is necessary to efficiently dispose the connector or jack in the case (side wall) of the personal computer.

Since it is desirable to further decrease the thickness of the personal computer in order to easily carry the personal computer, arrangement of particularly large functional components (the connector, the TV jack, or the like) should be carefully arranged.

A publication, JP-A-2006-311388, discloses a structure in which a bottom wall of a case is modified in accordance with the size of a large functional component.

The disclosure of JP-A-2006-311388 relates to an AV notebook-type personal computer, and discloses a speaker box structure. In the speaker box structure, in order to improve the volume or the sound quality by ensuring the speaker box volume, a part of a bottom wall of the case is formed as a convex shape, and the convex-shaped space is used as a part of the speaker box. Meanwhile, the convex-shaped portion serves as a tilt mechanism and a leg portion of the bottom wall of the case.

Incidentally, in recent years, the number of users carrying personal computers increases. For this reason, decreases in the thickness of the personal computer have rapidly advanced, and hence decreases in the thickness are more desirable. In addition, there is a demand for multiple functions of the personal computer together with the decrease in the thickness.

As described in JP-A-2006-311388, when the bottom wall of the case is modified in accordance with the comparatively large functional component, a decrease in the thickness cannot be achieved in a part of the case. In addition, as the comparatively large functional component, there is a connector or a TV jack in addition to the speaker box. For this reason, the decrease in the thickness cannot be realized and the design thereof is degraded when the structure of the bottom wall of the case is modified in accordance with such a functional component.

However, it is very difficult not to degrade the design while ensuring the decrease in the thickness and disposing many functional components in the case.

### BRIEF DESCRIPTION OF THE DRAWINGS

A general configuration that implements the various features of the present invention will be described with reference to the drawings. The drawings and the associated descriptions are provided to illustrate embodiments of the invention and not to limit the scope of the invention.

FIG. 1 is a perspective view showing an example of an external shape of an electronic device 11 according to an embodiment of the invention.

FIG. 2 is a perspective view showing an example of an external shape when the electronic device 11 is seen from the rear bottom side thereof.

FIG. 3 is a plan view of a bottom wall 30 of the electronic device 11.

FIG. 4 is a sectional view taken along the IV-IV line shown in FIG. 3.

FIG. 5 is a sectional view taken along the V-V line shown in FIG. 3.

FIG. 6 is a plan view when seen from a rear-side wall 34.

FIG. 7 is an enlarged view of an area surrounded by the dotted lines shown in FIG. 6.

### DETAILED DESCRIPTION

According to the embodiments described herein, there is provided an electronic device including: a case comprising a bottom wall; a leg portion that protrudes downward from the bottom wall and supports the case when the case is placed; and a functional component disposed above the leg portion, wherein the lowest point of the functional component is located at the same position as the height of the bottom wall or in the leg portion.

Embodiments according to the present invention will be described in detail with reference to the accompanying drawings. The scope of the claimed invention should not be limited to the examples illustrated in the drawings and those described in below.

An electronic device 11 according to an embodiment of the invention will be described with reference to the accompanying drawings.

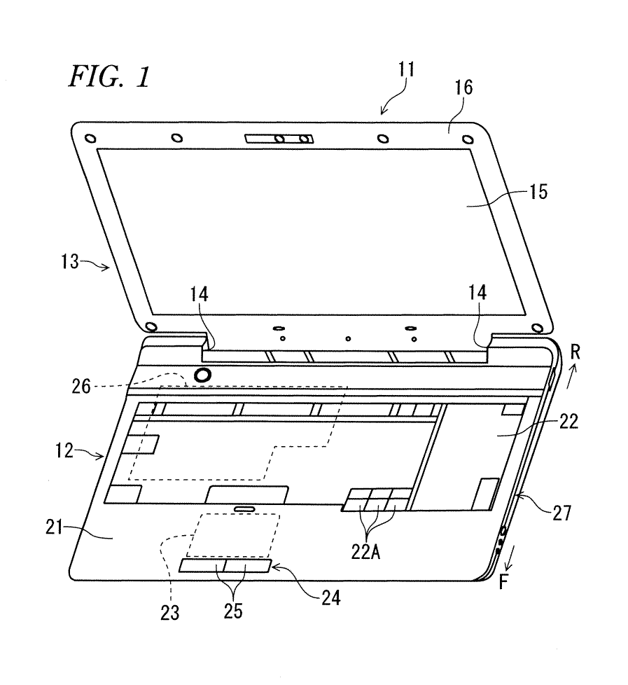

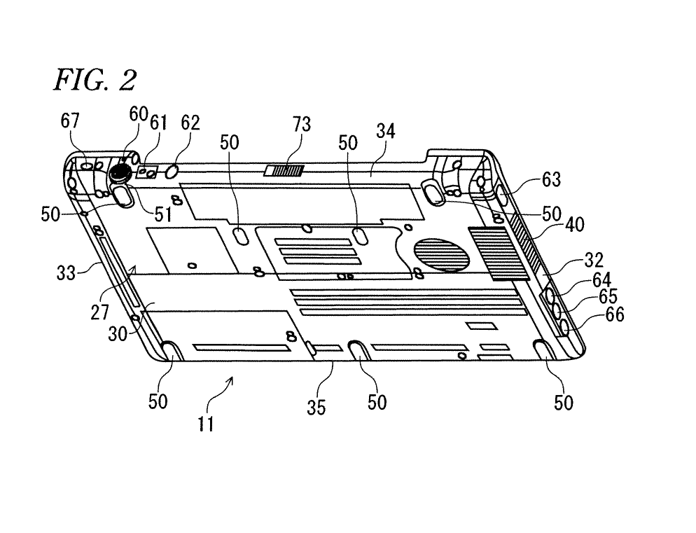

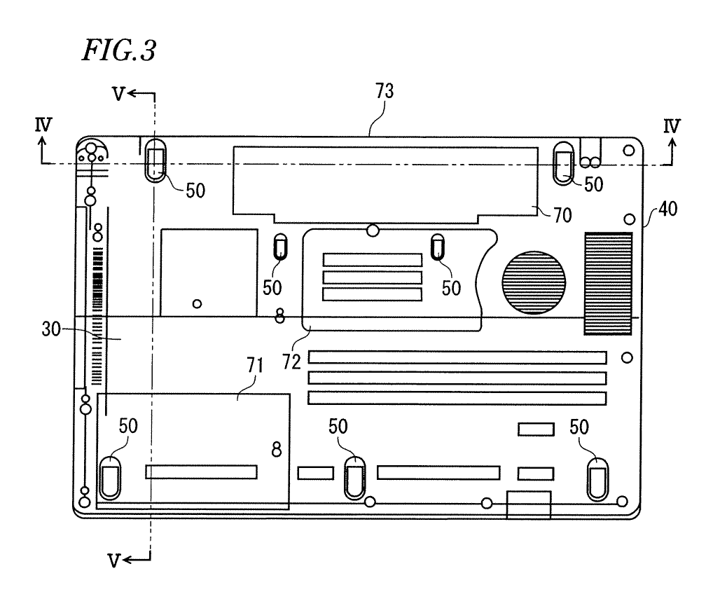

FIG. 1 is a perspective view showing an example of an external shape of an electronic device 11 according to an embodiment of the invention. FIG. 2 is a perspective view showing an example of an external shape when the electronic device 11 is seen from the rear bottom side thereof. FIG. 3 is a plan view of a bottom wall 30 of the electronic device 11. The electronic device 11 is, for example, a notebook-type personal computer.

In the specification, the front side (that is, a user side) is defined as a front direction F, the opposite side of the user is defined as a reverse direction R, the left side of the user is defined as the left direction, the right side of the user is defined as the right direction, the upside of the user is defined as the up direction, and the downside of the user is defined as the down direction.

As shown in FIGS. 1 to 3, a personal computer 11 as an example of an electronic device includes a main unit 12, a display unit 13, a hinge portion 14 which is provided between the main unit 12 and the display unit 13, and the like. The hinge portion 14 rotatably supports the display unit 13.

The display unit 13 includes a display 15, a display case 16 which is made from, for example, a synthetic resin so as to surround the periphery of the display 15, and the like. In the embodiment, a liquid crystal display is provided as an example of the display 15.

The main unit 12 includes an upper case 21 and a lower case 27, which are overlapped with each other so as to constitute the main unit 12. The surface of the upper case 21 is provided with a keyboard 22 which is used to input various information, a touch pad 23, an opening 24 which is provided in the upper case 21 so as to substantially have a rectangular shape, a pair of buttons 25 which is fitted into the opening 24, and the like. Only a part of a key 22A of the keyboard 22 is shown.

The display unit 13 is supported to the rear end of the main unit 12 through the hinge portion 14, and the display unit 13 is rotatable between a closed state and an open state. The closed state indicates a state where the display unit 13 is lain down on the main unit 12 so as to cover the keyboard 22 from the upside thereof. The open state indicates a state where the display unit 13 is raised up with respect to the main unit 12 so as to expose the keyboard 22 or the display 15.

The lower case 27 includes the bottom wall 30 and a plurality of side walls uprightly formed from the periphery of the bottom wall 30, and is formed as a thin box shape of which the upper portion is opened. A main substrate 26 mounted with various electronic components such as a power source circuit, a memory, or the like is accommodated in the lower case 27.

As shown in FIG. 2, the lower case 27 includes a rectangular bottom wall 30, a left-side wall 32, a right-side wall 33, a rear-side wall 34, and a front-side wall 35 which are uprightly formed from four sides in the periphery thereof, and the like.

Since the electronic components accommodated in the lower case 27 include a heating element such as a CPU which needs to be forcedly cooled, a cooling device such as a cooling fan or a cooling pin (not shown) used for cooling the heating element is also accommodated therein. In the cooling device such as the cooling fan or the cooling pin, a discharge port 40 is disposed in the peripheral portion (herein, the left-side wall 32) of the main unit 12 so as to discharge a cooling wind used for heat exchange to the outside.

The electronic device 11 is provided with various connectors used for connection to external device. The rear-side wall 34 is provided with a TV jack 60, a LAN connector 61, a DC connector 62, and the like. The left-side wall 32 is provided with an RGB connector 63, an eSATA connector 64, a HDMI connector 65, a USB connector 66, and the like. In addition, the rear-side wall 34 is provided with a battery ejection lever 73 used to extract a battery and an antitheft Kensington Lock 67 in addition to the connector. Further, the bottom wall 30 is provided with covers which cover various electronic components built in the electronic device 11, and for example, the covers correspond to a battery cover 70, an HDD (hard disk drive) cover 71, a memory cover 72, and the like.

In addition, for example, the electronic device 11 is provided with slide preventing members 50 which are formed by rubber members and provided at a plurality of positions of the bottom wall 30 so as to prevent the sliding of the body of the electronic device 11 while a user types using the keys 22A of the keyboard 22. In the bottom wall 30 of the electronic device 11, the slide preventing members 50 are provided at three positions of the front side (front direction F), two positions of the other side (rear direction R), and two positions in the vicinity of the center. The shape of each of the slide preventing members 50 is formed as a substantially rectangular shape which extends from the front-side wall 35 to the rear-side wall 34.

The electronic device 11 is provided with rectangular rubber leg portions 51 which directly protrude from the bottom wall 30 to the lower side so as to surround the periphery, and the slide preventing member 50 is adhered to the inside of the rectangular rubber leg portion 51. The slide preventing member 50 protrudes downward more than the rubber leg portion 51, and comes into contact with a ground contact surface of a placement table when the electronic device 11 is placed on the placement table.

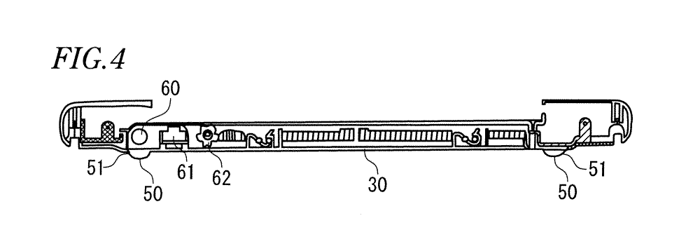

Next, the arrangement structure of the TV jack 60 of the electronic device 11 of the invention will be described with reference to FIGS. 4 to 7.

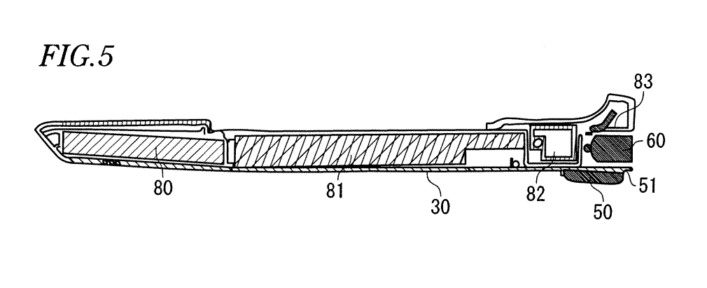

FIG. 4 is a sectional view taken along the IV-IV line shown in FIG. 3. In addition, FIG. 5 is a sectional view taken along the V-V line shown in FIG. 3.

As shown in FIGS. 4 and 5, the TV jack 60 is disposed in the upper position of the rubber leg portion 51 (or the slide preventing member 50). The TV jack 60 is electrically connected to a cable so as to receive information from an antenna, and the connected cable can be inserted thereto or extracted therefrom. When the cable is inserted thereto or extracted therefrom, frictional force occurs in the R direction and the F direction of the electronic device 11. The reason why the TV jack 60 is disposed at the upper position of the rubber leg portion 51 (or the slide preventing member 50) is because the frictional force can be reduced. In addition, as described above, since the slide preventing member 50 is formed to be elongated in the direction where the frictional force acts, the slide movement of the electronic device 11 can be suppressed when the cable is extracted from or inserted to the TV jack.

In addition, as shown in FIG. 5, the TV jack 60 extends in the longitudinal direction of the slide preventing member 50 and the F direction.

Further, a HDD 80, an ODD (optical disk driver) 81, a speaker device 82, and a hinge cover 83 are provided inside the electronic device 11.

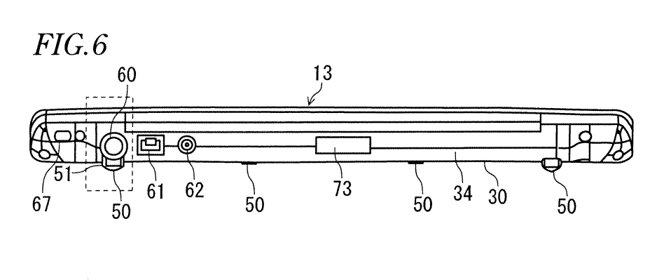

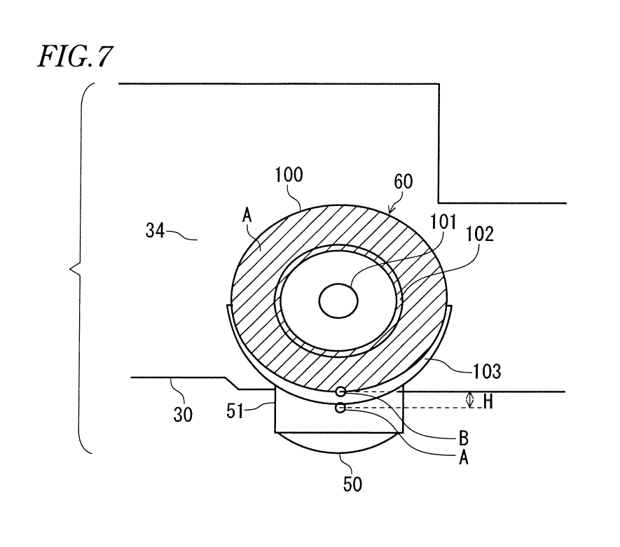

FIG. 6 is a plan view when seen from the rear-side wall 34. FIG. 7 is an enlarged view of an area surrounded by the dotted lines shown in FIG. 6.

As shown in FIG. 6, the TV jack 60 is a comparatively large functional component compared with functional components such as other connectors (for example, a LAN connector 61 or a DC connector 62). In the past, the bottom wall 30 was modified in accordance with the shape of the large functional component, but a decrease in the thickness cannot be realized due to the modification. Here, in the invention, the original structure is used not in accordance with the shape of the functional component. That is, the TV jack 60 is disposed at the upper position of the rubber leg portion 51 by using the original rubber leg portion 51. In the case where a further decrease in the thickness is demanded, the bottom wall 30 of the case needs to be pressed upward. However, when the bottom wall 30 is pressed upward, the large TV jack 60 is slightly sunk toward the bottom wall 30.

As shown in FIG. 7, the TV jack 60 includes a center conductor 101 and an outer conductor 102. The center conductor 101 is electrically connected to a conductive wire of the cable, and the outer conductor 102 is elastically supported so that the conductive wire of the cable is fitted to the center conductor 101. In addition, herein, the TV jack 60 also includes an accommodation hole 100 accommodating the center conductor 101 and the outer conductor 102.

In addition, a decoration portion 103 is provided at the lower position of the TV jack 60 by using the same material as that of the case (rear-side wall 34). The decoration portion 103 surrounds half the periphery of the TV jack 60, and in many cases, the decoration portion 103 is provided in the periphery of a hole such as a jack in consideration of design. Accordingly, when the TV jack 60 is mounted to the case, an area including the decoration portion 103 is set to a mounting area of the TV jack 60.

In addition, the point A (the lowest point of the decoration portion 103) located at the lower position of the decoration portion 103 is located at the lower position of the bottom wall 30 in the height direction by a distance H. That is, a part of the mounting area of the TV jack 60 is located in an area of the rubber leg portion 51. Since the accommodation hole 100 is also located at the lower position, the point B (the lowest point of the accommodation hole 100) located at the lower position of the accommodation hole 100 is lowered to the same position as the height of the bottom wall 30. In addition, no problem arises even when the point B of the accommodation hole 100 is located at the lower position of the bottom wall 30 so as to be located in an area of the rubber leg portion 51.

That is, since the bottom wall 30 is pressed more than the general structure due to a decrease in the thickness, the accommodation hole 100 is slightly sunk to the bottom wall 30 and the decoration portion 103 is slightly sunk toward the lower side of the rubber leg portion 51.

In the invention, a structure is adopted in which the TV jack 60 is provided at the upper position of the rubber leg portion 51 originally provided in the case, the TV jack 60 is lowered to the same position as the height of the bottom wall 30, and the decoration portion 103 is located in an area of a part of the rubber leg portion 51. Accordingly, it is possible to further decrease the thickness of the personal computer, and to accommodate a large functional component in the case. In addition, in the invention, the TV jack 60 is disposed at the upper position of the rubber leg portion 51, but functional components such as other connectors may be disposed in addition to the TV jack 60.

Although the embodiments according to the present invention have been described above, the present invention is not limited to the above-mentioned embodiments but can be variously modified. Component components disclosed in the aforementioned embodiments may be combined suitably to form various modifications. For example, some of all component components disclosed in the embodiments may be removed or may be appropriately combined.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic device comprising:
a case comprising a bottom wall;
a leg portion that protrudes downward from the bottom wall and supports the case when the case is placed; and
a functional component disposed above the leg portion,
wherein the lowest point of the functional component is located at the same position as the height of the bottom wall or in the leg portion.

2. The device of claim 1,
wherein the leg portion is formed as a substantially rectangular concave portion which directly protrudes downward from the bottom wall.

3. The device of claim 1,
wherein the functional component is a component which is used for a connection to an external device, the component comprising a jack or a connector.
